(19) United States
(12) Patent Application Publication
(10) Pub. No.: US 2011/0089477 A1
(43) Pub. Date: Apr. 21, 2011

(54) NANOSTRUCTURED MOS CAPACITOR

(75) Inventor: Lars-Erik Wernersson, Lund (SE)

(73) Assignee: QuNano AB, Lund (SE)

(21) Appl. No.: 12/997,737

(22) PCT Filed: Jun. 15, 2009
(86) PCT No.: PCT/SE2009/050734

§ 371 Date: Dec. 13, 2010

(30) Foreign Application Priority Data
Jun. 13, 2008 (SE) 0801393-0

(51) Int. Cl. H01L 29/93; H01L 21/04

(52) U.S. Cl. 257/312; 438/466; 257/E29.344; 257/E21.04

(57) ABSTRACT

The present invention provides nanostructured MOS capacitor that comprises a nanowire (2) at least partly enclosed by a dielectric layer (5) and a gate electrode (4) that encloses at least a portion of the dielectric layer (5). Preferably the nanowire (2) protrudes from a substrate (12). The gate electrode (4) defines a gated portion (7) of the nanowire (2), which is allowed to be fully depleted when a first predetermined voltage is applied to the gate electrode (4). A method for providing a variable capacitance in an electronic circuit by using such an nanostructured MOS capacitor is also provided. Thanks to the invention it is possible to provide a MOS capacitor having an increased capacitance modulation range. It is a further advantage of the invention to provide a MOS capacitor which has relatively low depletion capacitance compared to prior art MOS capacitances.

### TECHNICAL FIELD OF THE INVENTION

The present invention relates to MOS (metal-oxide-semiconductor) capacitors and in particular to capacitors having variable capacitance.

### BACKGROUND OF THE INVENTION

MOS capacitors are one of the fundamental building blocks for integrated circuits and they are frequently used for instance in voltage controlled oscillators. A wide range of modulation is often preferred. In the voltage controlled oscillators this increases the tuning range for the oscillator.

FIG. 1 schematically illustrates a prior art MOS capacitor comprising a gate electrode (E) arranged on a semiconductor substrate (S) with an intermediate dielectric layer (D). The semiconductor body is electrically connected to a body electrode (B) on the opposite side of the substrate (S). When a suitable voltage is applied to the gate electrode (E) a depletion region (A) is formed in the semiconductor substrate (S).

In a MOS capacitor the maximum capacitance, which commonly is referred to as accumulation capacitance, is set by the thickness and the permittivity of the intermediate dielectric layer, while the minimum capacitance, which commonly is referred to as the depletion capacitance, is set by the doping of the semiconductor substrate, and depends on the length of the depletion region. By changing the bias for the capacitor, the capacitance can be changed between the maximum and minimum values. Conventional MOS capacitors have an inherent limitation in the capacitance modulation range and the depletion capacitance is fairly high.

### SUMMARY OF THE INVENTION

In view of the foregoing one object of the present invention is to provide a MOS capacitor with a wide range of capacitance modulation and a low depletion capacitance. This is achieved by the nanostructured MOS capacitor and the method for varying a capacitance in an electric circuit by using a nanostructured MOS capacitor in accordance with the attached claims.

The nanostructured MOS capacitor according to the invention comprises a nanowire electrically connected to a first electrode, optionally a dielectric layer that covers at least a portion of the nanowire, and a gate electrode that covers at least a portion of the dielectric layer. At least a part of the nanowire and the first electrode function as the above-mentioned semiconductor body and body electrode, respectively. The gate electrode is an at least first radial layer arranged around at least a portion of the dielectric layer to form a gated portion having length L of the nanowire, and the dielectric layer is an at least second radial layer arranged around the nanowire along at least a portion of the nanowire.

In one embodiment of a nanostructured MOS capacitor in accordance with the present invention the whole nanowire cross-section of the gated portion is adapted to be completely depleted when a predetermined voltage is applied to the gate electrode.

Preferably the width of the nanowire 2 is less than 4 L, preferably less than 0.4 L, and more preferably less than 0.1 L.

Preferably the width of the nanowire 2 is less than 100 μm, preferably less than 60 μm, and more preferably less than 20 μm.

In other embodiment of the present invention the nanostructured MOS capacitor is used in an electric circuit for varying a capacitance, a voltage controlled oscillator device and a sample and hold circuit device.

Thanks to the invention it is possible to provide a MOS capacitor having an increased capacitance modulation range.

It is a further advantage of the invention to provide a MOS capacitor which has relatively low depletion capacitance compared to prior art MOS capacitances.

Embodiments of the invention are defined in the dependent claims. Other objects, advantages and novel features of the invention will become apparent from the following detailed description of the invention when considered in conjunction with the accompanying drawings and claims.

### BRIEF DESCRIPTION OF THE DRAWINGS

Preferred embodiments of the invention will now be described with reference to the accompanying drawings, wherein:

FIG. 1 is a schematic cross-sectional view of a MOS capacitor according to the prior art;

FIG. 2 is a schematic cross-sectional view of a nanostructured MOS capacitor according to one embodiment of the present invention;

FIG. 3 is a schematic cross-sectional view of a nanostructured MOS capacitor having a pyramidal shape according to another embodiment of the present invention;

FIG. 4a-d schematically illustrate one implementation of the present invention and experimental results from C(V) measurements thereon;

FIG. 5 schematically illustrate in (a) a theoretical fit of the C(V) dataset of FIG. 4d and (b-d) band bending and electron density at three different biases;

FIG. 6 is a circuit diagram of one embodiment of a voltage controlled oscillator device according to the present invention;

FIG. 7 is a circuit diagram of one embodiment of a sample and hold circuit according to the present invention;

FIG. 8 schematically illustrates a method for varying capacitance in an electric circuit according to one embodiment of the invention;

FIG. 9 schematically illustrates a nanostructured Schottky diode according to the present invention.

### DETAILED DESCRIPTION OF EMBODIMENTS

The present invention is based on using a nanowire to form a nanostructured MOS capacitor.

Nariowires are usually interpreted as one dimensional nanostructures that is in nanometer dimensions in its diameter. As the term nanowire implies it is the lateral size that is on the nanoscale whereas the longitudinal size is unconstrained. Such one dimensional nanostructures are commonly also referred to as nanowhiskers, one-dimensional nano-elements, nanorods, nanotubes, etc. Generally, nanowires are considered to have at least two dimensions each of which are not greater than 300 nm. However, the nanowires can have a diameter or width of up to about 1 μm. The one dimensional nature of the nanowires provides unique physical, optical and electronic properties. These properties can for example be used to form devices utilizing quantum mechanical effects or to form heterostructures of compositionally different materials that usually cannot be combined due to large lattice mismatch. On example is integration of semiconductor materials with reduced lattice-etching constraints and allow the growth of III-V structures on many semiconductor substrates such as Si substrates. As the term nanowire implies the one dimensional nature is often associated with an elongated shape. However, nanowires can also benefit from some of the unique properties without having an elongated shape. By way of example non-elongated nanowires can be formed on a substrate material having relatively large defect density in order to provide a defect-free template for further processing or in order to form a link between the substrate material and another material. Hence the present invention is not limited to an elongated shape of the nanowires. Since nanowires may have various cross-sectional shapes the diameter is intended to refer to the effective diameter.

FIG. 2 schematically illustrates one embodiment of a nanostructured MOS capacitor according to the present invention comprising a semiconductor nanowire 2 electrically connected to a first electrode 21, a dielectric layer 5, and a gate electrode 4. The nanowire 2 preferably protrudes from a substrate 12. The gate electrode 4 is formed by an at least first radial layer arranged around at least a portion of the dielectric layer 5, i.e. in a wrap gate configuration, to form a gated portion 7 of the nanowire 2. Thedielectric layer 5 is formed by an at least second radial layer arranged around the nanowire 2 along at least a portion of the nanowire 2, and it should be appreciated that this gated portion 7 and the gate electrode in principle corresponds to the above-mentioned semiconductor body and body electrode, respectively. By way of example, as illustrated in FIG. 2, the dielectric layer 5 fully encloses the nanowire 2 and the gate electrode 4 completely covers the dielectric layer 5. Optionally an insulating layer 14 encloses a base portion of the nanowire 2 to electrically separate the gate electrode 4 from the substrate 12.

Referring to FIG. 2, in one embodiment of a nanostructured MOS capacitor in accordance with the present invention the whole nanowire 2 cross-section of the gated portion 7 is adapted to be completely depleted when a predetermined voltage is applied to the gate electrode 4. By way of example the nanostructured MOS capacitor of this embodiment comprises a nanowire 2 having a cylindrical shape with a radius R or width W (W=2R) and a length L of the gated portion 7. In accumulation mode the capacitance of such a cylindrical nanostructured MOS capacitor is determined by the total surface area 2πRL (πWL) of the gated portion of the nanowire 2, whereas in depletion mode the capacitance is determined by the nanowire cross sectional area πR² (πR²/4). The invention is not limited to cylindrical nanowire geometries, and hence the capacitance-determining areas may be defined differently than in the above equations. However, irrespective of the particular geometry the present invention is based on the possibility to have, due to the nanowire technology, different capacitance-determining areas depending on whether the capacitor is operating in the depletion mode or in the accumulation mode.

The accumulation and depletion modes are determined by threshold levels for the voltage applied to the gate electrode 4. If nanowire 2 is made of a p-type material, the gated portion 7 of the nanowire 2 is adapted to be fully depleted when a voltage higher than a first predetermined threshold level is applied to the gate electrode 4. On the other hand if the nanowire 2 is made of an n-type material, the gated portion 7 of the nanowire 2 is adapted to be fully depleted when a voltage lower than a second predetermined threshold level is applied to the gate electrode 4.

The change in device area according to the present invention, when changing from accumulation mode to depletion mode, improves the modulation capability of the MOS capacitor. Basically the depletion capacitance can approach zero, which is a unique feature for the nanowire 2 geometry and not possible with conventional MOS capacitors as described with reference to FIG. 1 wherein both the accumulation capacitance and the depletion capacitances are determined by essentially the same area, i.e. the effective device area is essentially constant.

For a nanostructured MOS capacitor in accordance with one embodiment of the present invention that comprises a cylindrical nanowire 2 the capacitance, when changing capacitance-determining areas, is reduced if the width of the nanowire 2 is less than four times the length of the gated portion 7 of the nanowire 2. Preferably the width of the nanowire 2 is less than 0.4 L, and even more preferably the width of the nanowire is less than 0.1 L. A decrease of the width-to-length-ratio (W/L) gives an increased change in capacitance when changing from accumulation mode to depletion mode. To establish the complete depletion of the nanowire 2 and to provide a low depletion capacitance the width or radius of the nanowire should be small. Preferably the radius R of the nanowire 2 is less than 50 μm, preferably less than 30 μm, and more preferably less than 10 μm, i.e. the width is less than 100 μm, preferably less than 60 μm, and more preferably less than 20 μm

As understood by a skilled person, nanowires are readily processed in parallel and thus an array of nanostructured MOS capacitors can be fabricated on a common substrate. A predetermined capacitance of a nanostructured MOS capacitor device can be obtained, for example, by connecting at least a group of nanowires of an array in parallel or in series. Another possibility to vary the capacitance is to vary the dimensions, i.e. the length and the thickness of the nanowire 2, or to vary the composition or thickness of the dielectric layer.

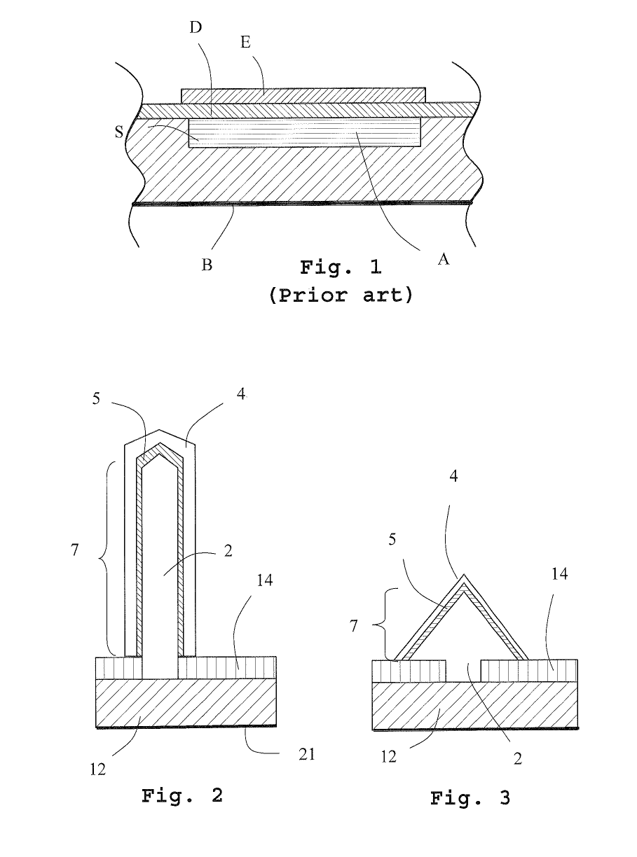

Referring to FIG. 3, in one embodiment of the present invention the nanostructured MOS capacitor comprises a semiconductor nanowire 2 protruding from a substrate 12 through a hole in an insulating growth mask 14. During growth of the nanowire 2 the growth conditions are adapted to provide an upper portion of the nanowire 2 above the growth mask 14 having a pyramidal shape. A gate electrode 4 and an intermediate dielectric layer 5 enclose the upper portion, i.e. the gated portion, of the nanowire 2 to allow formation of a depletion region 7 when a suitable voltage is applied to the gate electrode .

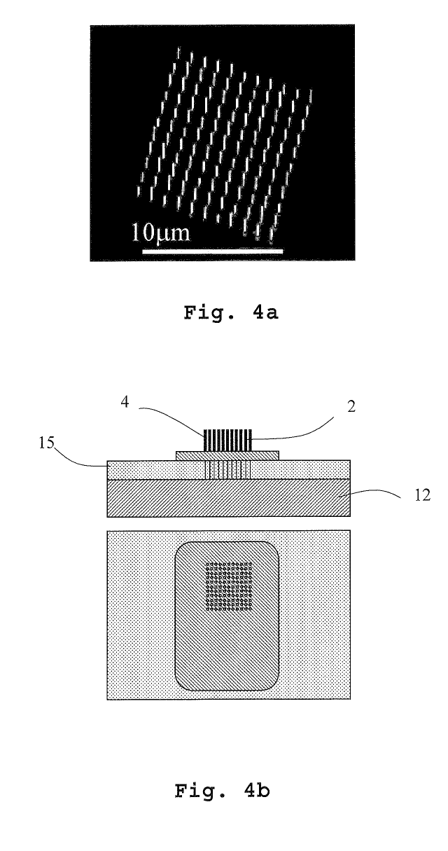

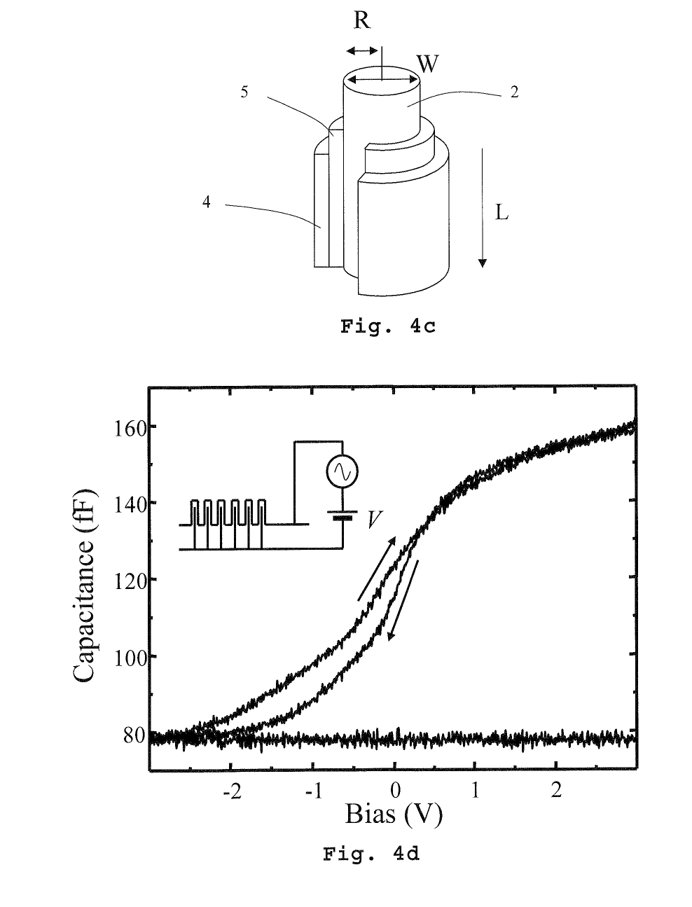

FIGS. 4a-c illustrates one implementation of a nanostructured MOS capacitor of the present invention. Nanowire arrays, as in the SEM micrograph in FIG. 4a, were obtained by self-assembled growth in a chemical beam epitaxy (CBE) system, however the present invention is not limited to this growth technology. As appreciated by a person skilled in the art nanowires can be fabricated using (Metal-Organic Chemical Vapour Deposition) MOCVD, vapour-liquid-solid-processes (VLS), molecular beam epitaxy (MBE) or the like. Nanowire formation was guided by gold nanoparticles that were deposited on a doped InAs (111) B substrate. For the purpose of making a study of the CV-performance of nanostructured MOS capacitors with respect to nanowire dimensions a plurality of arrays was established in parallel using various nanoparticle sizes. 5 different groups of 15 nominally identical nanowire arrays were fabricated with an average nanowire radius of 23.0 nm, 25.0 nm, 26.5 nm, 28.5 nm and 30.0 nm, respectively. The nanowires 2 were first insulated by a conformal HfO₂ coating with a thickness of about 10 nm by atomic layer deposition (125 cycles at 250° C.) to form a dielectric layer 5 enclosing at least along a portion of the circumferential surface of the nanowires 2. A gate electrode 4 was formed by sputtering a Cr/Au bilayer having a nominal thickness of about 20 nm. A polymeric film of S1813 from Shipley with a thickness of about 1 μm was deposited as a lifting layer 15 in order to increase the ratio between the capacitance of the nanowires and the stray capacitance of the device originating from e.g. parallel capacitance between contact pads and the substrate. The gated nanowire length L was in average 680 nm. Single devices were defined by UV lithography and metal etching of 30-45 μm² gate pads. As illustrated in FIG. 4d it has been experimentally demonstrated that the capacitance of this MOS capacitor device reaches the background capacitance, i.e. the capacitance of a bare pad without any nanowires, and that there is essentially no depletion capacitance. The experimental results of the diagram in FIG. 4d was obtained by a C(V) scan from −3V to +3V on 26.5 nm nanowires at frequency of 20 MHz.

The dielectric layer 5 and the gate electrode 4 may enclose only a portion of the nanowire 2 or the full length thereof. In one embodiment of a nanostructured capacitor according to the invention a nanowire protrudes through a hole in an insulating growth mask 14. A dielectric layer 5 and a gate electrode 4 extend along the length of the nanowire 2 and enclose the circumferential surface thereof while leaving an end portion free for an electrical connection.

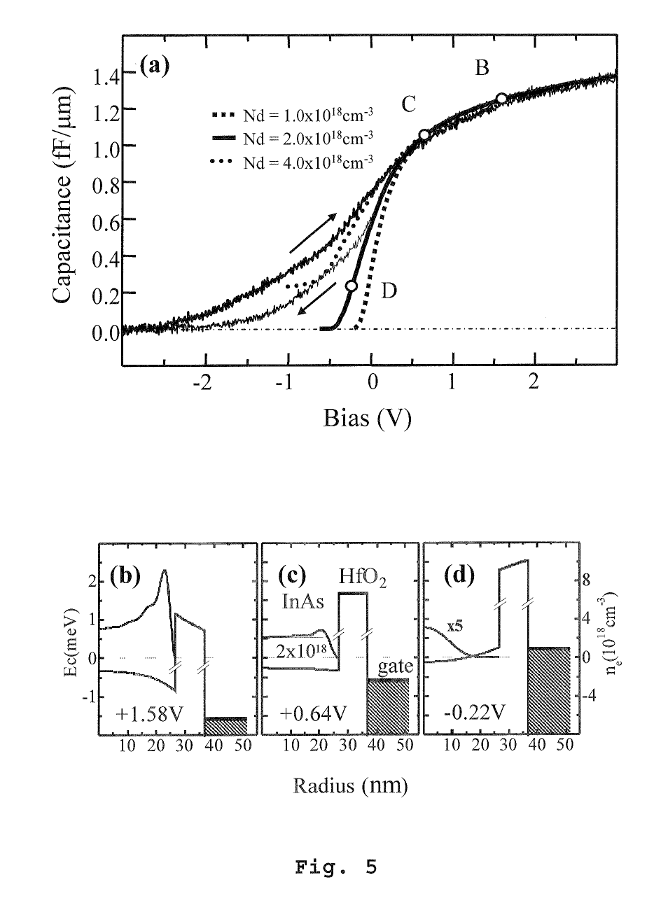

FIG. 5a schematically illustrates a theoretical fit of the C(V) dataset of FIG. 4d using three different charge carrier densities, N_{d}=1.0×10¹⁸ cm⁻³, N_{d}=2.0×10¹⁸ cm⁻³, and N_{d}=4.0×10¹⁸ cm⁻³, in the nanowires of the nanostructured MOS capacitor of FIGS. 4a-c. FIG. 5b-d schematically illustrate the band bending and electron density at three different points B, C, D along the line for N_{d}=2.0×10¹⁸ cm⁻³ as indicated in FIG. 5a. The different points B, C, D correspond to accumulation, flatband and depletion conditions, respectively. The theoretical fit was based on calculations for the capacitance on the basis of a Poisson-Schroedinger code similar to that described in E. Gnani et al., Solid State Elecronics 50, 709 (2006) and L. Wang et al., Solid-State Electronics 50, 1732 (2006).

One embodiment of the present invention provides an electrical circuit comprising a nanostructured MOS transistor for providing a variable capacitance.

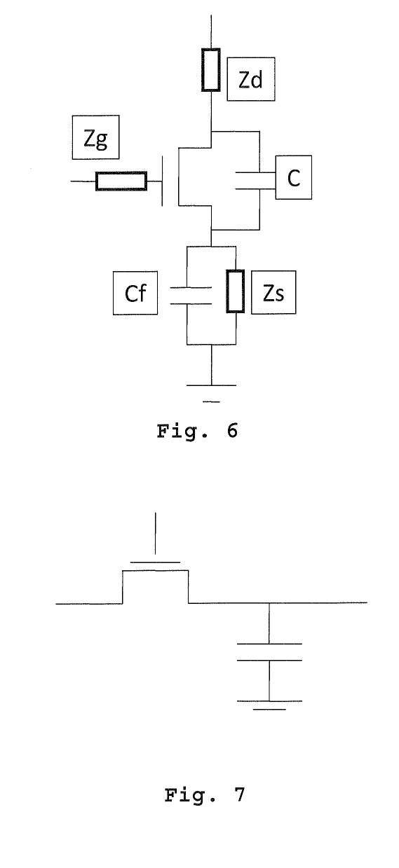

Referring to FIG. 6, a voltage controlled oscillator device according to the present invention comprises a nanostructured MOS capacitor according to the invention. The nanostructured MOS capacitor comprises a nanowire 2 at least partly enclosed by a dielectric layer 5 and a gate electrode 4 that enclosed at least a portion of the dielectric layer 5. Preferably the nanowire 2 protrudes from a substrate 12. The voltage controlled oscillator device may be designed as illustrated in the circuit diagram of FIG. 6, however other implementations are possible. One advantage with the voltage controlled oscillator device is that it comprises capacitors having very low depletion capacitance. Thus, enhanced frequency modulation can be obtained.

Referring to FIG. 7, a sample and hold circuit device according to the present invention comprises a nanostructured MOS capacitor according to the invention. The nanostructured MOS capacitor comprises a nanowire 2 at least partly enclosed by a dielectric layer 5 and a gate electrode 4 that enclosed at least a portion of the dielectric layer 5. Preferably the nanowire 2 protrudes from a substrate 12. The sample and hold circuit device may be designed in the circuit diagram of FIG. 6, however other implementations are possible. One advantage with the sample and hold circuit device is that it comprises capacitors having very low depletion capacitance. Thus, the resolution of such an device can be increased.

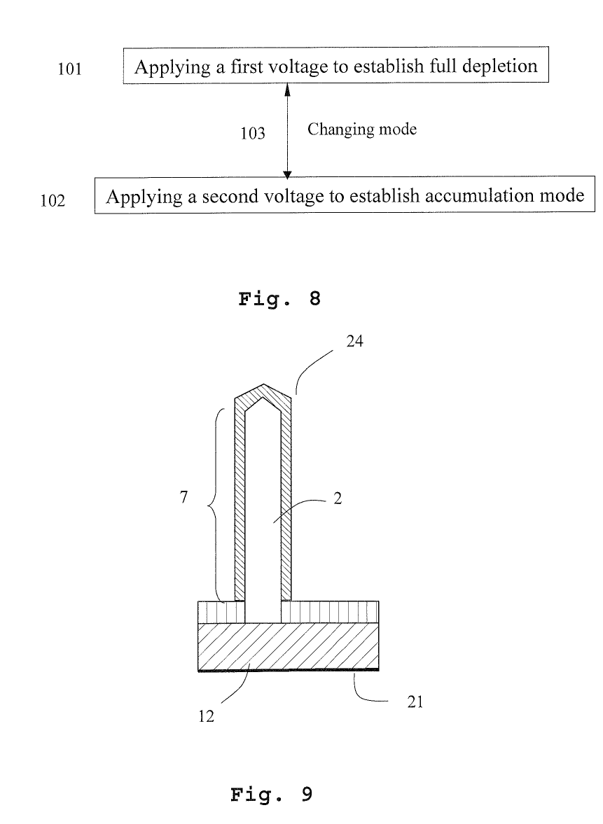

Referring to FIG. 8, a method of providing a variable capacitance in an electronic circuit by using a nanostructured MOS capacitor comprising a nanowire 2 that protrudes from a substrate 12, a dielectric layer 5 formed by an at least second radial layer arranged around the nanowire 2 along at least a portion of the nanowire 2, and a gate electrode 4 formed by ai a first radial layer arranged around at least a portion of the dielectric layer 5 to form a gated portion 7 of the nanowire 2, in accordance with the present invention is characterised by the steps of:
101 applying a first predetermined voltage to the gate electrode 4 to fully deplete the gated portion 7 of the nanowire 2.

The method preferably further comprises the step of 102 applying a second predetermined voltage to the gate electrode 4 to establish accumulation mode.

By varying a voltage applied to the gate electrode 4 the capacitance can be varied and in one embodiment the method comprises the steps of 103 altering between accumulation mode and depletion mode. As described above the capacitance may be defined by different capacitance-determining areas depending on whether the capacitor is operating in the depletion mode or in the accumulation mode by appropriate dimensioning of the nanostructured MOS capacitor.

While the invention has been described for single nanowires it is to be understood that a very large number (few to millions of) nanowires can be collectively used as capacitors in identical fashions.

Suitable materials for the substrate of the nanostructured MOS capacitor include, but is not limited to: Si, GaAs, GaP, GaP:Zn, GaAs, InAs, InP, GaN, Al₂O₃, SiC, Ge, GaSb, ZnO, InSb, SOI (silicon-on-insulator), CdS, ZnSe, CdTe. Suitable materials for the nanowires include, but is not limited to IV, III-V, II-VI semiconductors such as: GaAs, InAs, Ge, ZnO, InN, GaInN, GaN AlGaInN, BN, InP, InAsP, GaInP, InGaP:Si, InGaP:Zn, GaInAs, AlInP, GaAlInP, GaAlInAsP, GaInSb, InSb and Si. Possible donor dopants are, but not limited to, Si, Sn, Te, Se, S, etc, and acceptor dopants are Zn, Fe, Mg, Be, Cd, etc.

Although the present invention has been described in terms of nanostructured MOS capacitors, it should be appreciated that the above mentioned effect of switching between different capacitance determining areas can be utilized for other semiconductor devices such as a Schottky diode. In principle the Schottky diode functions as a MOS capacitor. A nanostructured Schottky diode according to one embodiment of the invention comprises a semiconductor nanowire 2 or an array of semiconductor nanowires protruding from a semiconductor substrate 12 or optionally a buffer layer on a semiconductor substrate 12. At least a portion of the nanowire is enclosed by a metallic contact 24 defining a gated portion 7 of the nanowire, whereby a junction between the metallic contact 24 and the semiconductor nanowire 2 forms a Schottky barrier. The metallic contact and a first electrode 21, which is connected to the nanowire via the buffer layer and/or the substrate or via a wrap contact enclosing a part of the nanowire not enclosed by the metallic contact, form a two-terminal device. The nanowire geometry enables formation of nearly defect-free materials in the device and a high packing density. In particular, wide-bandgap semiconductors such as GaN, InGaN, AlGaN, SiC, which are preferred materials for Schottky diodes, can be used. When compared to Si diodes these materials offer higher performance in terms of breakdown voltage, lower leakage currents, higher temperature stability, faster reverse recovery times and positive temperature coefficients of resistance. Suitable materials for the metallic contact are metallic materials comprising one or more of Mg, Hf, Ag, Al, W, Au, Pd or Pt. The buffer layer, which may be a III-V material comprising GaN, InN, InGaN, InP, GaAs or GaP, can be used also for the other embodiments described above.

As appreciated by the skilled person the dielectric layer 5 may comprise other materials than oxides, although the term MOS (metal-oxide-semiconductor) indicates that the dielectric material should be an oxide. The dielectric layer may be made of HfO₂ as disclosed above but also other dielectric materials such as for example Al₂O₃, ZrO₂, Si₃N₄ and Ga₂O₃ can be used.

While the invention has been described in connection with what is presently considered to be the most practical and preferred embodiments, it is to be understood that the invention is not to be limited to the disclosed embodiments, on the contrary, it is intended to cover various modifications and equivalent arrangements within the appended claims.

1. A nanostructured MOS capacitor comprising a nanowire that protrudes from a substrate , and a gate electrode formed by a first radial layer arranged around at least a portion of the nanowire to form a gated portion of the nanowire.

2. A nanostructured MOS capacitor according to claim 1, further comprising a dielectric layer formed by an at least second radial layer arranged around the nanowire along at least a portion of the nanowire.

3. The nanostructured MOS capacitor according to claim 1, wherein the gated portion of the nanowire is adapted to be fully depleted when a first predetermined voltage is applied to the gate electrode.

4. The nanostructured MOS capacitor according to claim 3, wherein the gated portion of the nanowire has a length L and a width W, and the width W is less than 4 L.

5. The nanostructured MOS capacitor according to claim 4, wherein the MOS capacitor in accumulation mode and in depletion mode has a capacitance proportional to WL and W², respectively.

6. The nanostructured MOS capacitor according to claim 4, wherein W is less than 100 μm.

7. The nanostructured MOS capacitor according to claim 1, wherein the gate electrode is a metallic contact and the metallic contact and the nanowire forms a Schottky barrier.

8. An electrical circuit comprising a nanostructured MOS capacitor according to claim 1 for providing a variable capacitance.

9. A voltage controlled oscillator device comprising the nanostructured MOS capacitor according to claim 1.

10. A sample and hold circuit device comprising the nanostructured MOS capacitor according to claim 1.

11. A method of providing a variable capacitance in an electronic circuit by using a nanostructured MOS capacitor comprising:
a nanowire that protrudes from a substrate;
a dielectric layer formed by an at least second radial layer arranged around the nanowire along at least a portion of the nanowire; and
a gate electrode formed by a first radial layer arranged around at least a portion of the dielectric layer defining a gated portion of the nanowire;
the method comprising applying a first predetermined voltage to the gate electrode to fully deplete the gated portion of the nanowire.

12. The method according to claim 11, further comprising the step of applying a second predetermined voltage to the gate electrode to establish accumulation mode.

13. The method according to claim 12, further comprising the step of altering between accumulation mode and depletion mode, wherein the capacitance is defined by different capacitance-determining areas depending on whether the capacitor is operating in the depletion mode or in the accumulation mode.

14. The method according to claim 12, wherein the gated portion of the nanowire has a length L and a width W, and the nanostructured MOS capacitor in accumulation mode and in depletion mode has a capacitance proportional to WL and W², respectively.

15. The nanostructured MOS capacitor according to claim 3, wherein the gated portion of the nanowire has a length L and a width W, and the width W is less than 0.4 L.

16. The nanostructured MOS capacitor according to claim 3, wherein the gated portion of the nanowire has a length L and a width W, and the width W is less than 0.1 L.

17. The nanostructured MOS capacitor according to claim 4, wherein W is less than 60 μm.

18. The nanostructured MOS capacitor according to claim 4, wherein W is less than 20 μm.
